(19) United States
(12) Patent Application Publication
(10) Pub. No.: US 2002/0192944 A1
(43) Pub. Date: Dec. 19, 2002

(54) Method and apparatus for controlling a thickness of a copper film

(76) Inventors: Thomas J. Sonderman, Austin, TX (US); Scott Bushman, Richardson, TX (US); Craig William Christian, Buda, TX (US)

Correspondence Address: Terry D. Morgan, Williams, Morgan & Amerson, P.C., Suite 250, 7676 Hillmont, Houston, TX, 77040, US

(21) Appl. No.: 09/880,975

(22) Filed: Jun. 13, 2001

(51) Int. Cl. H01L 21/4763; H01L 21/44

(52) U.S. Cl. 438/637; 438/687

(57) ABSTRACT

A system for controlling the thickness of a layer of copper in the formation of a semiconductor device is provided. The system is comprised of an electroplate tool, a metrology tool, and a controller. The electroplate tool is capable of depositing a layer of copper on a surface of a semiconductor device. The electroplate tool has at least one parameter that may be varied to control a thickness of the layer of copper. The metrology tool is capable of measuring the thickness of the copper layer and delivering a signal indicative thereof. The controller is adapted for receiving the signal, comparing the measured thickness to a desired thickness, and varying the at least one parameter in response to the measured thickness differing from the desired thickness

### BACKGROUND OF THE INVENTION

1. Field of the Invention

This invention relates generally to semiconductor fabrication technology, and, more particularly, to techniques for controlling copper electroplating.

2. Description of the Related Art

There is a constant drive within the semiconductor industry to increase the operating speed of integrated circuit devices, e.g., microprocessors, memory devices, and the like. This drive is fueled by consumer demands for computers and electronic devices that operate at increasingly greater speeds. This demand for increased speed has resulted in a continual reduction in the size of semiconductor devices, e.g., transistors. That is, many components of a typical field effect transistor (FET), e.g., channel length, junction depths, gate dielectric thickness, and the like, are reduced. For example, all other things being equal, the smaller the channel length of the FET, the faster the transistor will operate. Thus, there is a constant drive to reduce the size, or scale, of the components of a typical transistor to increase the overall speed of the transistor, as well as integrated circuit devices incorporating such transistors. Additionally, reducing the size, or scale, of the components of a typical transistor also increases the density, and number, of the transistors that can be produced on a given amount of wafer real estate, lowering the overall cost per transistor as well as the cost of integrated circuit devices incorporating such transistors.

However, reducing the size, or scale, of the components of a typical transistor also requires reducing the size and cross-sectional dimensions of electrical interconnects to contacts to active areas, such as N⁺ (P⁺) source/drain regions and a doped-polycrystalline silicon (doped-polysilicon or doped-poly) gate conductor, and the like. As the size and cross-sectional dimensions of electrical interconnects get smaller, resistance increases and electromigration increases. Increased resistance and electromigration are undesirable for a number of reasons. For example, increased resistance may reduce device drive current, and source/drain current through the device, and may also adversely affect the overall speed and operation of the transistor. Additionally, electromigration effects in aluminum (Al) interconnects, where electrical currents actually carry aluminum (Al) atoms along with the current, causing them to electromigrate, may lead to degradation of the aluminum (Al) interconnects, further increased resistance, and even disconnection and/or delamination of the aluminum (Al) interconnects.

The ideal interconnect conductor for semiconductor circuitry will be inexpensive, easily patterned, have low resistivity, and high resistance to corrosion, electromigration, and stress migration. Aluminum (Al) is most often used for interconnects in contemporary semiconductor fabrication processes primarily because aluminum (Al) is inexpensive and easier to etch than, for example, copper (Cu). However, because aluminum (Al) has poor electromigration characteristics and high susceptibility to stress migration, it is typical to alloy aluminum (Al) with other metals.

As discussed above, as semiconductor device geometries shrink and clock speeds increase, it becomes increasingly desirable to reduce the resistance of the circuit metallization. The one criterion that is most seriously compromised by the use of aluminum (Al) for interconnects is that of conductivity. This is because the three metals with lower resistivities (aluminum, Al, has a resistivity of 2.824×10⁻⁶ ohms-cm at 20° C.), namely, silver (Ag) with a resistivity of 1.59×10⁻⁶ ohms-cm (at 20° C.), copper (Cu) with a resistivity of 1.73×10⁻⁶ ohms-cm (at 20° C.), and gold (Au) with a resistivity of 2.44×10⁻⁶ ohms-cm (at 20° C.), fall short in other significant criteria. Silver (Ag), for example, is relatively expensive and corrodes easily, and gold (Au) is very costly and difficult to etch. Copper (Cu), with a resistivity nearly on par with silver (Ag), a relatively high immunity to electromigration, high ductility and high melting point (1083° C. for copper, Cu, vs. 660° C. for aluminum, Al), fills most criteria admirably. However, copper (Cu) is difficult to etch in a semiconductor environment. As a result of the difficulty in etching copper (Cu), an alternative approach to forming vias and metal lines must be used. The damascene approach, consisting of etching openings such as trenches in the dielectric for lines and vias and creating in-laid metal patterns, is the leading contender for fabrication of sub-0.25 micron (sub-0.25μ) design rule copper-metallized (Cu-metallized) circuits.

In the damascene approach, a layer or film of copper is formed over the surface of the dielectric, filling the openings and/or trenches. The excess copper is then removed by polishing, grinding, and/or etching to leave only the copper in the openings or trenches. When the layer of copper is formed, sufficient care should be taken to ensure that the layer is thick enough to completely fill the openings and/or trenches. Underfilling the openings and/or trenches may produce undesirable voids, increased resistance, poor electrical contact, etc., which may impede performance. Overfilling the openings and/or trenches can dramatically increase the amount of copper used, increase the time needed to form the copper layer, increase the time needed to remove the excess copper, and generally slow the manufacturing process.

The present invention is directed to overcoming, or at least reducing the effects of, one or more of the problems set forth above.

### SUMMARY OF THE INVENTION

In one aspect of the present invention, a method is provided. The method comprises forming a first dielectric layer above a first structure layer. A first opening is formed in the first dielectric layer, and a first copper layer is formed above the first dielectric layer and in the first opening. Thereafter, an actual thickness of the copper layer is measured and compared to a desired thickness. At least one parameter used to form the first copper layer is varied in response to the actual thickness differing from the desired thickness.

In another aspect of the present invention, a system is provided. The system is comprised of an electroplate tool, a metrology tool, and a controller. The electroplate tool is capable of depositing a layer of copper on a surface of a semiconductor device. The electroplate tool has at least one parameter that may be varied to control a thickness of the layer of copper. The metrology tool is capable of measuring the thickness of the copper layer and delivering a signal indicative thereof. The controller is adapted for receiving the signal, comparing the measured thickness to a desired thickness, and varying the at least one parameter in response to the measured thickness differing from the desired thickness.

### BRIEF DESCRIPTION OF THE DRAWINGS

The invention may be understood by reference to the following description taken in conjunction with the accompanying drawings, in which the leftmost significant digit(s) in the reference numerals denote(s) the first figure in which the respective reference numerals appear, and in which:

FIGS. 1-8 schematically illustrate a single-damascene copper interconnect process flow according to various embodiments of the present invention;

FIG. 9 schematically illustrates multiple layers of copper interconnects according to various embodiments of the present invention;

FIG. 10 schematically illustrates one embodiment of a control system useful in manufacturing semiconductor devices having features of the type illustrated in FIGS. 1-9;

FIG. 11 schematically illustrates one embodiment of a semiconductor manufacturing tool useful in forming a layer or film of copper; and

FIGS. 12-13 illustrate, in flowchart form, one embodiment of a control scheme for the system of FIG. 10.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but, on the contrary, the intention is to cover all modifications, equivalents, and alternatives falling within the spirit and scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

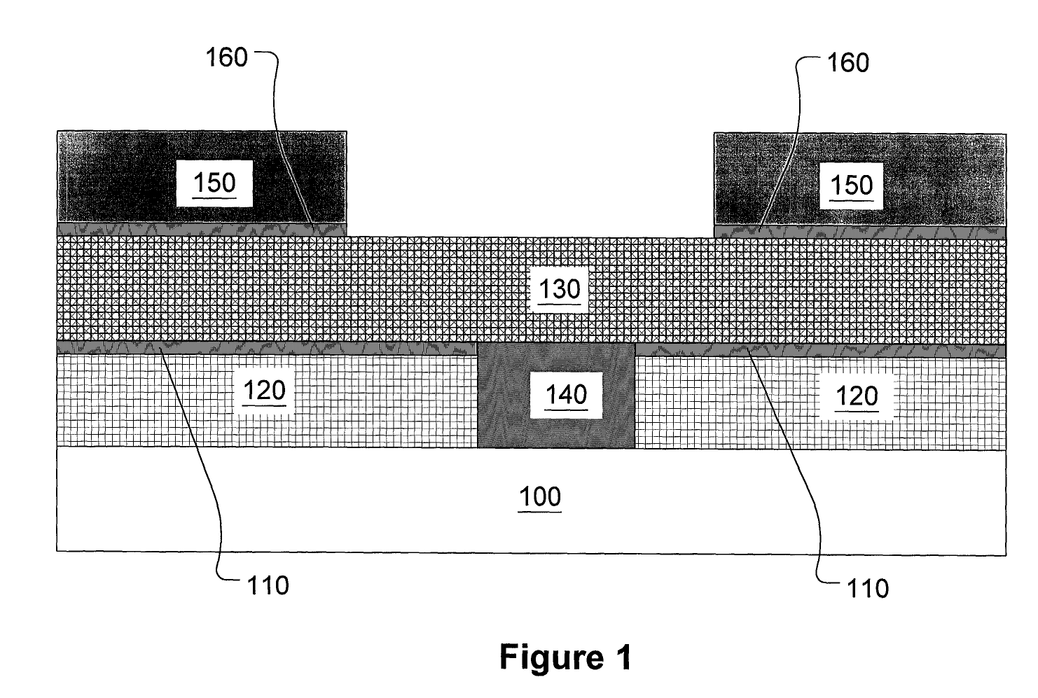

Illustrative embodiments of a method for semiconductor device fabrication according to the present invention are shown in FIGS. 1-13. Although the various regions and structures of a semiconductor device are depicted in the drawings as having very precise, sharp configurations and profiles, those skilled in the art recognize that, in reality, these regions and structures are not as precise as indicated in the drawings. Nevertheless, the attached drawings are included to provide illustrative examples of the present invention.

In general, the present invention is directed towards the manufacture of a semiconductor device. As will be readily apparent to those skilled in the art upon a complete reading of the present application, the present method is applicable to a variety of technologies, for example, NMOS, PMOS, CMOS, and the like, and is readily applicable to a variety of devices, including, but not limited to, logic devices, memory devices, and the like.

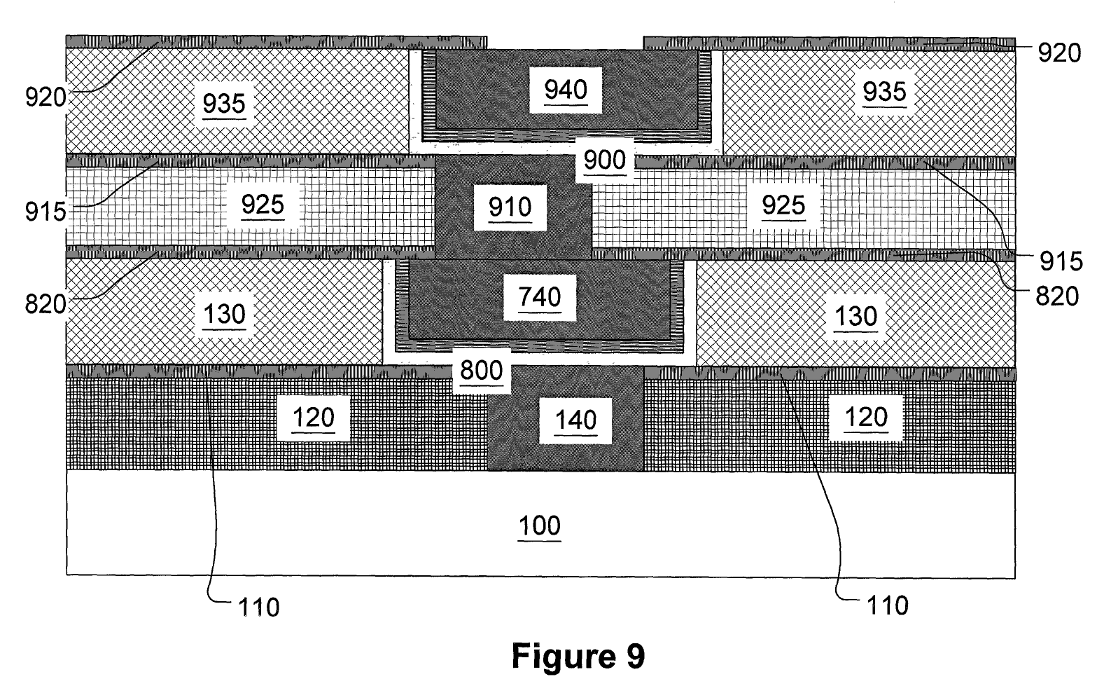

As shown in FIG. 1, a first dielectric layer 120 and a first conductive structure 140 (such as a copper intermetal via connection) may be formed above a structure layer 100 such as a semiconducting substrate. However, the present invention is not limited to the formation of a copper (Cu)-based interconnect above the surface of a semiconducting substrate such as a silicon wafer, for example. Rather, as will be apparent to one skilled in the art upon a complete reading of the present disclosure, a copper (Cu)-based interconnect formed in accordance with the present invention may be formed above previously formed semiconductor devices and/or process layer, e.g., transistors, or other similar structure. In effect, the present invention may be used to form process layers on top of previously formed process layers. The structure layer 100 may be an underlayer of semiconducting material, such as a silicon substrate or wafer, or, alternatively, may be an underlayer of semiconductor devices, such as a layer of metal oxide semiconductor field effect transistors (MOSFETs), and the like, and/or a metal interconnection layer or layers (see FIG. 9, for example) and/or an interlevel (or interlayer) dielectric (ILD) layer or layers, and the like.

In a single-damascene copper process flow, according to various embodiments of the present invention, as shown in FIGS. 1-8, the first dielectric layer 120 is formed above the structure layer 100, adjacent the first conductive structure 140. As shown in FIG. 1, the first dielectric layer 120 has an etch stop layer (ESL) 110 (typically silicon nitride, Si₃N₄, or SiN, for short) formed and patterned thereon, between the first dielectric layer 120 and a second dielectric layer 130 and adjacent the first conductive structure 140. The second dielectric layer 130 is formed above the etch stop layer (ESL) 110 and above the first conductive structure 140. The first dielectric layer 120 has the first conductive structure 140 disposed therein. If necessary, the second dielectric layer 130 may have been planarized using a chemical-mechanical polishing (CMP) process. The second dielectric layer 130 has an etch stop layer 160 (typically also SiN) formed and patterned thereon, between the second dielectric layer 130 and a patterned photomask 150. The patterned photomask 150 is formed and patterned above the etch stop layer 160.

The first and second dielectric layers 120 and 130 may be formed from a variety of dielectric materials, including, but not limited to, materials having a relatively low dielectric constant (low K materials, where K is less than or equal to about 4), although the dielectric materials need not have low dielectric constants. The first and second dielectric layers 120 and 130 may be formed by a variety of known techniques for forming such layers, e.g., a chemical vapor deposition (CVD) process, a low-pressure CVD (LPCVD) process, a plasma-enhanced CVD (PECVD) process, a sputtering process, a physical vapor deposition (PVD) process, a spin-on coating process (such as a spin-on glass process), and the like, and each may have a thickness ranging from approximately 3000 Å-8000 Å, for example.

The first and second dielectric layers 120 and 130 may be formed from a variety of low K dielectric materials, where K is less than or equal to about 4. Examples include Applied Material's Black Diamond®, Novellus' Coral®, Allied Signal's Nanoglass®, JSR's LKD5104, and the like. In one illustrative embodiment, the first and second dielectric layers 120 and 130 are each comprised of Applied Material's Black Diamond®, each having a thickness of approximately 5000 Å, each being formed by being blanket-deposited by an LPCVD process for higher throughput.

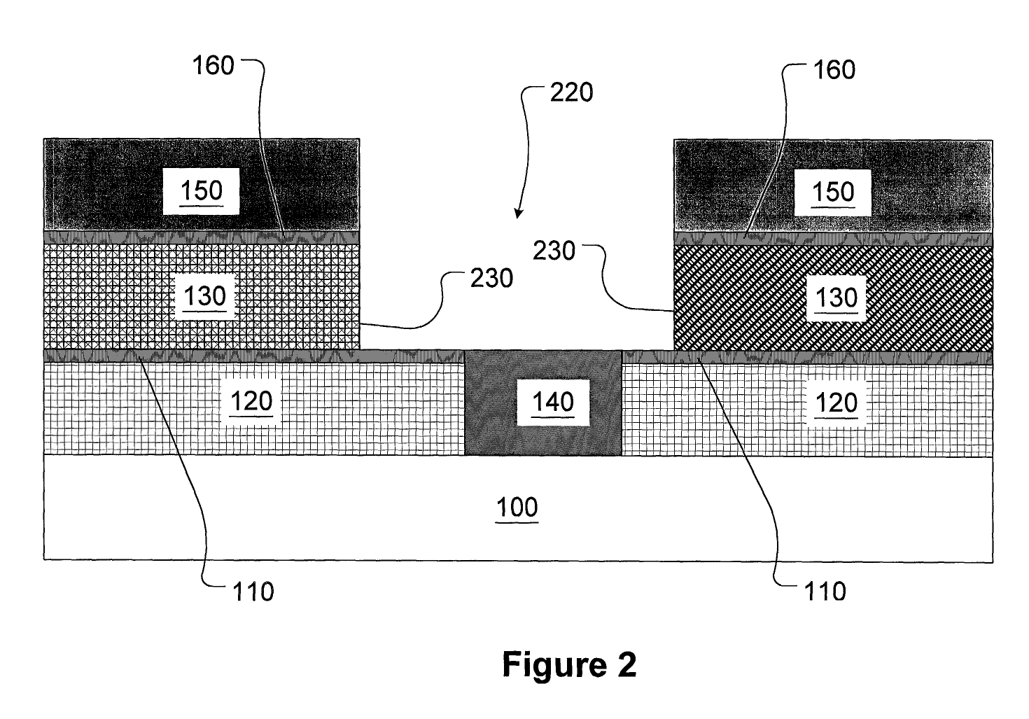

As shown in FIG. 2, a metallization pattern is then formed by using a patterned photomask 150, the etch stop layers 160 and 110 (FIGS. 1-2), and photolithography. For example, openings (such as an opening or trench 220 formed above at least a portion of the first conductive structure 140) for conductive metal lines, contact holes, via holes, and the like, are etched into the second dielectric layer 130 (FIG. 2). The opening 220 has sidewalls 230. The opening 220 may be formed by using a variety of known anisotropic etching techniques, such as a reactive ion etching (RIE) process using hydrogen bromide (HBr) and argon (Ar) as the etchant gases, for example. Alternatively, an RIE process with CHF₃ and Ar as the etchant gases may be used, for example. Plasma etching may also be used in various illustrative embodiments. The etching may stop at the etch stop layer 110 and at the first conductive structure 140.

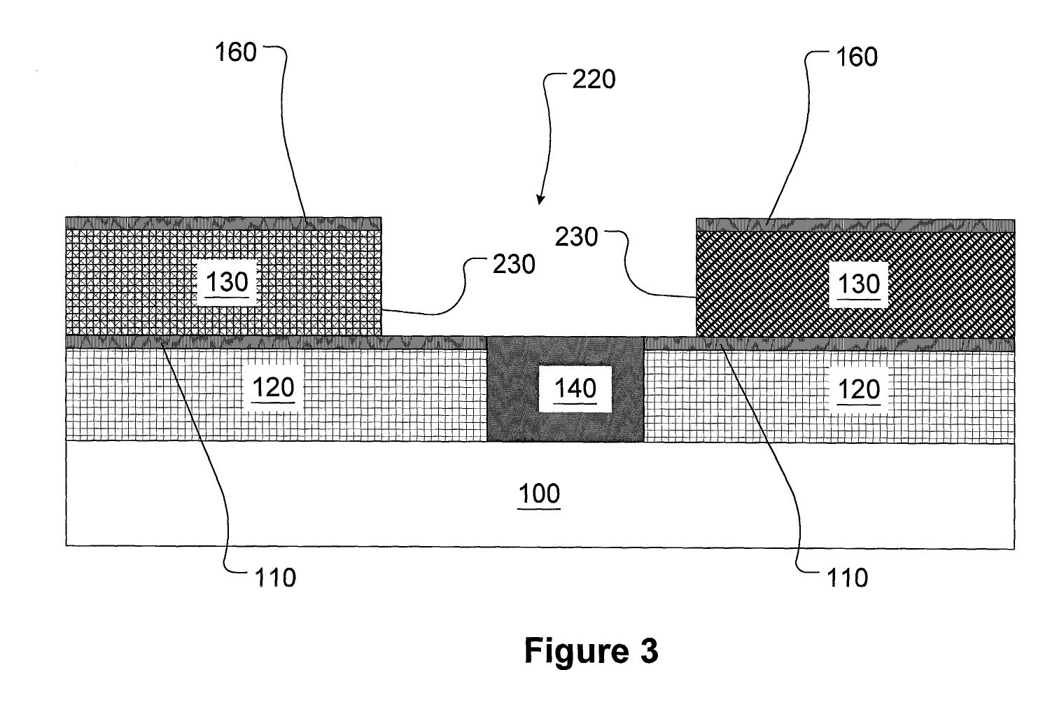

As shown in FIG. 3, the patterned photomask 150 (FIGS. 1-2) is stripped off, by ashing, for example. Alternatively, the patterned photomask 150 may be stripped using a 1:1 solution of sulfuric acid (H₂SO₄) to hydrogen peroxide (H₂O₂), for example.

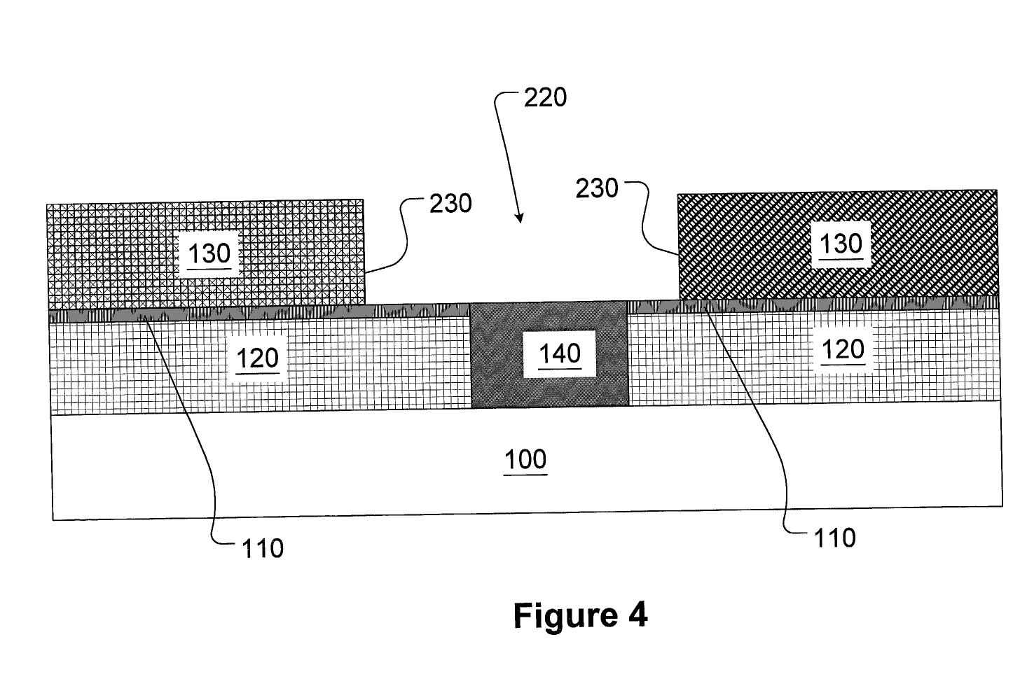

As shown in FIG. 4, the etch stop layer 160 is then stripped off, by selective etching, for example. In various illustrative embodiments, for example, in which the etch stop layer 160 comprises silicon nitride (Si₃N₄), hot aqueous phosphoric acid (H₃PO₄) may be used to selectively etch the silicon nitride (Si₃N₄) etch stop layer 160.

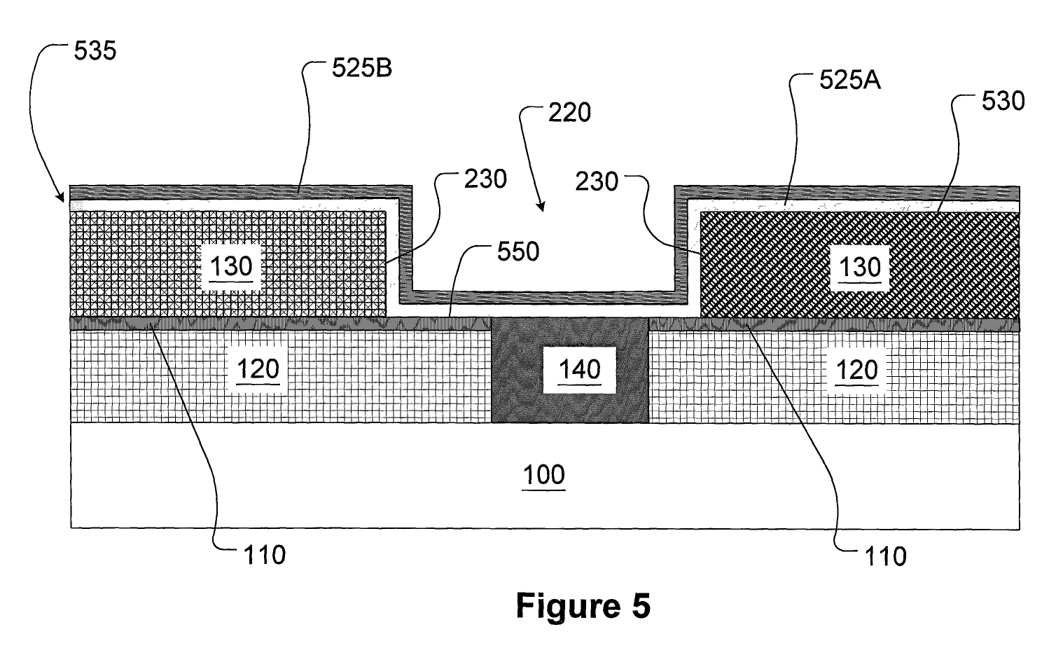

As shown in FIG. 5, a thin barrier metal layer 525A and a copper seed layer 525B (or a seed layer of another conductive material) are applied to the entire surface using vapor-phase deposition. The barrier metal layer 525A and the copper (Cu) seed layer 525B blanket-deposit an entire upper surface 530 of the second dielectric layer 130 as well as the side surfaces 230 and a bottom surface 550 of the opening 220, forming a conductive surface 535, as shown in FIG. 5.

The barrier metal layer 525A may be formed of at least one layer of a barrier metal material, such as tantalum (Ta) or tantalum nitride (TaN), and the like, or, alternatively, the barrier metal layer 525A may be formed of multiple layers of such barrier metal materials. For example, the barrier metal layer 525A may also be formed of titanium nitride (TiN), titanium-tungsten, nitrided titanium-tungsten, magnesium, a sandwich barrier metal Ta/TaN/Ta material, or another suitable barrier material. Tantalum nitride (TaN) is believed to be a good diffusion barrier to copper (Cu). Tantalum (Ta) is believed to be easier to deposit than tantalum nitride (TaN), while tantalum nitride (TaN) is easier to subject to a chemical mechanical polishing (CMP) process than tantalum (Ta). The copper seed layer 525B may be formed on top of the one or more barrier metal layers 525A by physical vapor deposition (PVD) or chemical vapor deposition (CVD), for example.

The bulk of the copper trench-fill is frequently done using an electroplating technique, where the conductive surface 535 is mechanically clamped to an electrode (not shown) to establish an electrical contact, and the structure layer 100 and overlying layers are then immersed in an electrolyte solution containing copper (Cu) ions. An electrical current is then passed through the workpiece-electrolyte system to cause reduction and deposition of copper (Cu) on the conductive surface 535. In addition, an alternating-current bias of the workpiece-electrolyte system has been considered as a method of self-planarizing the deposited copper (Cu) film, similar to the deposit-etch cycling used in high-density plasma (HDP) tetraethyl orthosilicate (TEOS) dielectric depositions.

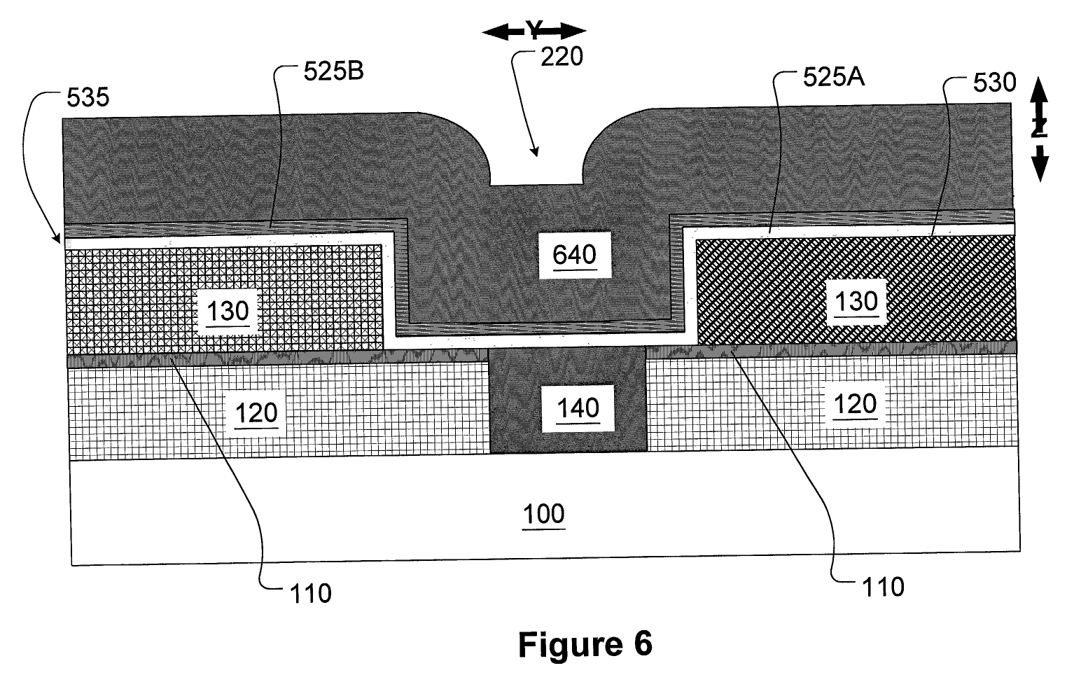

As shown in FIG. 6, this process typically produces a conformal coating of a copper (Cu) layer 640 of substantially constant thickness across the entire conductive surface 535. The copper (Cu) layer 640 may then be annealed using a rapid thermal anneal (RTA) process performed at a temperature ranging from approximately 100-400° C. for a time ranging from approximately 10-180 seconds. Alternatively, the copper (Cu) layer 640 may be annealed using a furnace anneal process at a temperature ranging from approximately 100-400° C. for a time ranging from approximately 10-90 minutes. In various alternative embodiments, the copper (Cu) layer 640 may be annealed using a rapid thermal anneal (RTA) process performed at a temperature ranging from approximately 250-350° C. for a time ranging from approximately 10-180 seconds. In still other various illustrative embodiments, the copper (Cu) layer 640 may be annealed using a furnace anneal process at a temperature ranging from approximately 250-350° C. for a time ranging from approximately 10-90 minutes.

A post-formation anneal may be used to accelerate room-temperature grain growth in the copper (Cu) layer 640, and, consequently, may affect the mechanical stress state of the copper (Cu) layer 640. In particular, the post-formation anneal of over-filled damascene openings, such as opening 220 shown in FIG. 6, affects the mechanical stress state of the copper (Cu) layer 640. For anneals performed at temperatures ranging from about 150-400° C., the copper (Cu) layer 640 is in a relatively low mechanical stress state that is effectively mechanical stress-free, or slightly compressive, since the copper (Cu) has no native oxide strengthening mechanism and since the copper (Cu) grain size is small. The copper (Cu) grain growth in the small-grained copper (Cu) layer 640 under compression will act to relax the mechanical stress. In the copper (Cu) in the opening 220 covered by the sufficiently thick layer of the copper (Cu) layer 640, it is likely that the mechanical stress in the copper (Cu) would be about zero or at least very small at the anneal temperatures ranging from about 150-400° C. The microstructure of the copper (Cu) in the opening 220 is influenced by the sufficiently thick layer of the copper (Cu) layer 640, and it is believed that the mechanical stress in the copper (Cu) in the opening 220 is also influenced by the sufficiently thick layer of the copper (Cu) layer 640.

Upon cooling from the anneal, the mechanical stress in the copper (Cu) in the opening 220 is tensile. Since the copper (Cu) of the copper (Cu) layer 640 has a thickness, measured from the bottom of the opening 220, in a range of approximately 3000 Å-8000 Å, for example, the mechanical stress in the copper (Cu) in the opening 220 is relatively small, with hydrostatic stresses in a range of from about 50 MPa to about 200 MPa.

The mechanical stress in the copper (Cu) in the opening 220 is tensile, after cooling down from the anneal, due in part to the difference in the coefficient of thermal expansion (ACTE) between the copper (Cu) in the copper (Cu) layer 640 and the semiconducting material of the structure layer 100. For example, the coefficient of thermal expansion (CTE) for silicon (Si) is about 2.6×10⁻⁶/° C., the coefficient of thermal expansion (CTE) for copper (Cu) is about 16.6×10⁻⁶/° C., and the coefficient of thermal expansion (CTE) for aluminum (Al) is about 23.1×10⁻⁶/° C. Therefore, the difference in the coefficient of thermal expansion (ACTE) between copper (Cu) and silicon (Si) is about 14.0×10⁻⁶/° C. For the sake of comparison, the difference in the coefficient of thermal expansion (ACTE) between aluminum (Al) and silicon (Si) is about 20.5×10⁻⁶/° C., or about 1.46 times larger than the difference in the coefficient of thermal expansion (ACTE) between copper (Cu) and silicon (Si). The difference in the coefficient of thermal expansion (ACTE) is the dominant source of mechanical strain in a metallic interconnect.

The mechanical stress may be calculated from the mechanical strain using mechanical stiffness coefficients. An order of magnitude estimate of the mechanical stress may be calculated using the biaxial modulus. The biaxial modulus of silicon (Si) is about 1.805×10⁵ MPa (MegaPascals), the biaxial modulus of copper (Cu) is about 2.262×10⁵ MPa, and the biaxial modulus of aluminum (Al) is about 1.143×10⁵ MPa, or about half the biaxial modulus of copper (Cu).

In one illustrative embodiment, copper (Cu) lines having critical dimensions of about 0.25 μm, and a thickness of approximately 4500 Å, similar to the copper (Cu) layer 640, are subjected to a post-plating anneal using a furnace anneal process performed at a temperature of approximately 250° C. for a time of approximately 30 minutes. The mechanical stresses measured along the lengths (X direction, into the page of FIG. 6) of these copper (Cu) lines are about 300 MPa, the mechanical stresses measured along the widths (Y direction, horizontal arrows in FIG. 6) of these copper (Cu) lines are about 160 MPa, and the mechanical stresses measured along the heights (Z direction, horizontal arrows in FIG. 6) of these copper (Cu) lines are about 55 MPa. The hydrostatic mechanical stress measured with these copper (Cu) lines is about 175 MPa.

These mechanical stress levels appear to be a function of the post-plating anneal temperature. By way of comparison, copper (Cu) lines having critical dimensions of about 0.25 μm, and a thickness of approximately 4500 Å, similar to the copper (Cu) layer 640, subjected to a post-plating anneal using a furnace anneal process performed at a higher temperature of approximately 500° C. for the same time of approximately 30 minutes have been measured to have the following mechanical stresses. The mechanical stresses measured along the lengths (X direction) of these copper (Cu) lines are about 600 MPa, the mechanical stresses measured along the widths (Y direction) of these copper (Cu) lines are about 470 MPa, and the mechanical stresses measured along the heights (Z direction) of these copper (Cu) lines are about 230 MPa. The hydrostatic mechanical stress measured with these copper (Cu) lines is about 440 MPa. Since hydrostatic mechanical stress is the driving force for void formation in metallic interconnects, efforts should be made to reduce this hydrostatic mechanical stress. Thus, the post-plating anneal temperature should be lowered to reduce this hydrostatic mechanical stress. For example, a post-plating furnace anneal process performed at approximately 250° C. for approximately 30 minutes, which produces a hydrostatic mechanical stress of about 175 MPa, is preferable to a post-plating furnace anneal process performed at approximately 500° C. for approximately 30 minutes, which produces a hydrostatic mechanical stress of about 440 MPa.

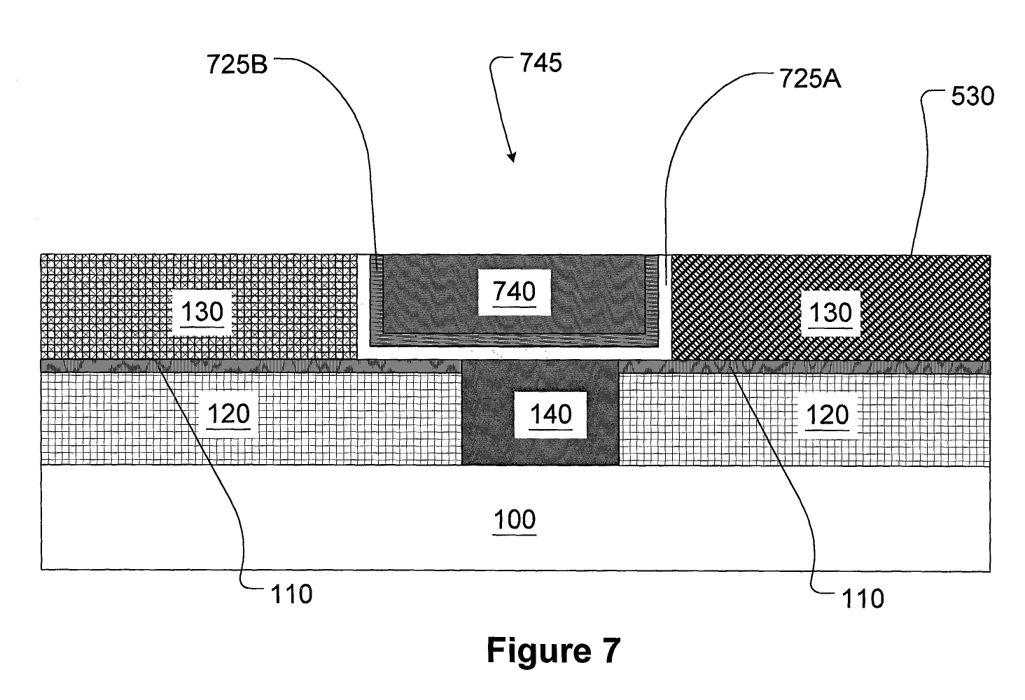

As shown in FIG. 7, following the post-deposition anneal described above, the layer of the copper (Cu) layer 640 is planarized using chemical mechanical polishing (CMP) techniques. The planarization using CMP clears all copper (Cu) and barrier metal from the entire upper surface 530 of the second dielectric layer 130, leaving a copper (Cu) portion 740 of the copper (Cu) layer 640 remaining in a metal structure such as a copper (Cu)-filled trench, forming a copper (Cu)-interconnect 745, adjacent remaining portions 725A and 725B of the one or more barrier metal layers 525A and copper seed layer 525B (FIGS. 5 and 6), respectively, as shown in FIG. 7.

As shown in FIG. 7, the copper (Cu)-interconnect 745 may be formed by annealing the copper (Cu) portion 740, adjacent the remaining portions 725A and 725B of the one or more barrier metal layers 525A and copper seed layer 525B (FIGS. 5 and 6), to the first conductive structure 140. The anneal process may be performed in a traditional tube furnace, at a temperature ranging from approximately 100-500° C., for a time period ranging from approximately 10-90 minutes, in a nitrogen-containing ambient that may include at least one of ammonia (NH₃), molecular nitrogen (N2), molecular hydrogen (H₂), argon (Ar), and the like. Alternatively, the anneal process may be a rapid thermal anneal (RTA) process performed at a temperature ranging from approximately 100-500° C. for a time ranging from approximately 10-180 seconds in a nitrogen-containing ambient that may include at least one of molecular nitrogen (N2), molecular hydrogen (H₂), argon (Ar), and the like.

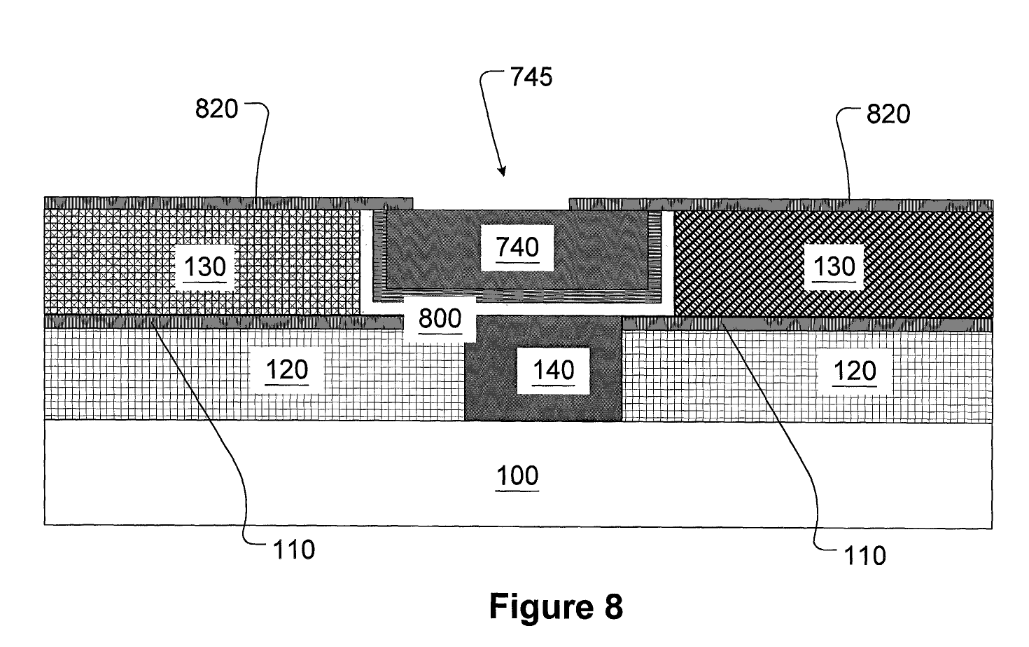

As shown in FIG. 8, the second dielectric layer 130 may be planarized, as needed, using chemical mechanical polishing (CMP) techniques. Planarization would leave the planarized second dielectric layer 130 adjacent the copper (Cu)-interconnect 745 and above the etch stop layer 110, forming a copper (Cu)-interconnect layer 800. The copper (Cu)-interconnect layer 800 may include the copper (Cu)-interconnect 745 adjacent the second dielectric layer 130. The copper (Cu)-interconnect layer 800 may also include the etch stop layer 110. As shown in FIG. 8, the copper (Cu)-interconnect layer 800 may also include an etch stop layer 820 (also known as a “hard mask” and typically formed of silicon nitride, Si₃N₄, or SiN, for short) formed and patterned above the second dielectric layer 130 and above at least a portion of the copper (Cu)-interconnect 745.

As shown in FIG. 9, the copper (Cu)-interconnect layer 800 may be an underlying structure layer (similar to the structure layer 100) to a copper (Cu)-interconnect layer 900. The copper (Cu)-interconnect layer 900 may include a copper (Cu)-filled trench 940 and an intermetal via connection 910 adjacent a planarized dielectric layer 935. The intermetal via connection 910 may be a copper (Cu) structure similar to the first copper (Cu) structure 140, and the intermetal via connection 910 may be annealed to the copper (Cu)-filled trench 940 in a similar fashion to the anneal described above in relation to the formation of the copper (Cu)-interconnect 745 (FIG. 7). The copper (Cu)-interconnect layer 900 may also include the etch stop layer 820 and/or etch stop layer 915 and/or etch stop layer 920 (also known as “hard masks” and typically formed of silicon nitride, Si₃N₄, or SiN, for short) formed and patterned above the planarized dielectric layers 925 and/or 935, respectively. The etch stop layer 920 may also be formed above at least a portion of the copper (Cu)-filled trench 940.

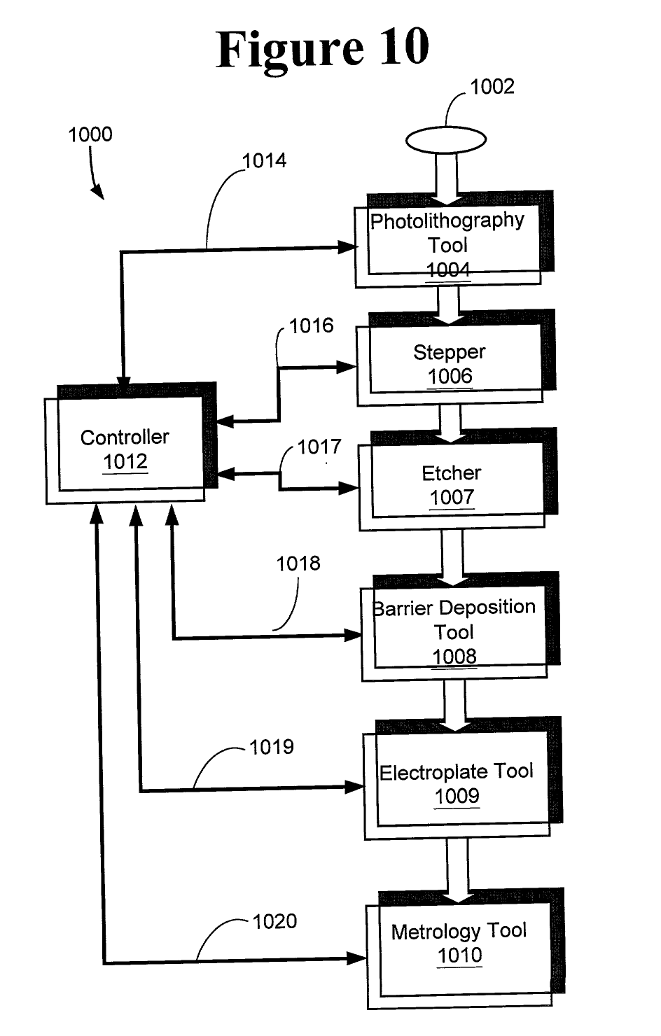

Turning now to FIG. 10, one illustrative embodiment of a system 1000 that may be used to produce the features of the semiconductor device depicted in FIGS. 1-9 is shown. The system 1000 processes wafers 1002 and is generally comprised of a photolithography tool 1004, a stepper 1006, an etcher 1007, a barrier deposition tool 1008, an electroplate tool 1009, a metrology tool 110, and a controller 1012. The wafer 1002 is generally serially processed within each of the tools 1004-1009, and then analyzed in the metrology tool 1010. Those skilled in the art will appreciate that more or fewer tools may be included in the system 1000 as is warranted to produce the desired features on the wafer 1002.

Generally, the photolithography tool 1004 forms a layer of photoresist on the wafer 1002. The stepper 1006 controllably exposes the layer of photoresist to a light source through a mask or reticle to produce a desired pattern in the layer of photoresist. The etcher 1007 removes those portions of layers underlying the layer of photoresist that are exposed by the patterning produced by the mask to produce openings and/or holes in a desired pattern. The thin barrier metal layer is deposited by a barrier deposition tool 1008. The electroplate tool 1009 forms a layer or film of copper on the surface of the wafer 1002, filling the openings and/or holes. The metrology tool 1010 measures select parameters of the wafer 102, such as physical characteristics and/or electrical properties. The measured physical characteristics may include thickness of the copper layer, feature sizes, depth of an etching process, etc. The measured electrical properties may include resistance, conductivity, voltage levels, etc. In some embodiments, the metrology tool 1010 may not be needed, as sufficient feedback information for controlling parameters of the tools 1004-1009 may be obtained from sensors within the tools 1004-1009.

The metrology tool 1010 may be any of a variety of devices used to measure electrical and/or structural features on the wafer 1002 after being processed by the tools 1004-1009. For example, the metrology tool 1010 may be configured to measure feature sizes on the wafer 1002, such as the thickness of the copper layer, and provide the measurement data to the controller 1012. Measurements of this type may be useful in determining whether the electroplating process has produced a layer of copper having a desired thickness, and then modifying the operation of the electroplate tool 1009, if necessary, so that subsequently processed wafers 1002 have the desired thickness. Such a metrology tool is available from Rudolph Technolgies as model number 200, Tencor as Model NC110, or the like. It is contemplated that in some embodiments of the instant invention additional tools (not shown) may be deployed in the manufacturing line, such as additional metrology tools 1010 positioned to measure certain mechanical or electrical parameters of the wafer 1002 at various steps in the manufacturing process. Alternatively, additional tools may be deployed intermediate the etcher 1007 and the electroplate tool 1009. These intermediate devices may perform additional processes, such as cleaning, rinsing, forming additional layers, etc. Moreover, it is anticipated that the formation of some of the features on the wafer 1002 will be produced by operations performed by the tools 1004-1009 other than in the order illustrated. For example, it may be useful to route the wafer 1002 through the photolithography tool 1004, stepper 1006 and etcher 1007 a plurality of times before delivering the wafer 1002 to the electroplate tool 1009.

The etcher 1007 may be any of a variety of devices capable of removing underlying process layers not protected by the layer of photoresist. For example, an etcher commercially available from Applied Materials as model 5000-DPS may be used. Any of a variety of etchants may be employed without departing from the spirit and scope of the instant invention. In one exemplary embodiment, the etcher 1007 employs plasma etching.

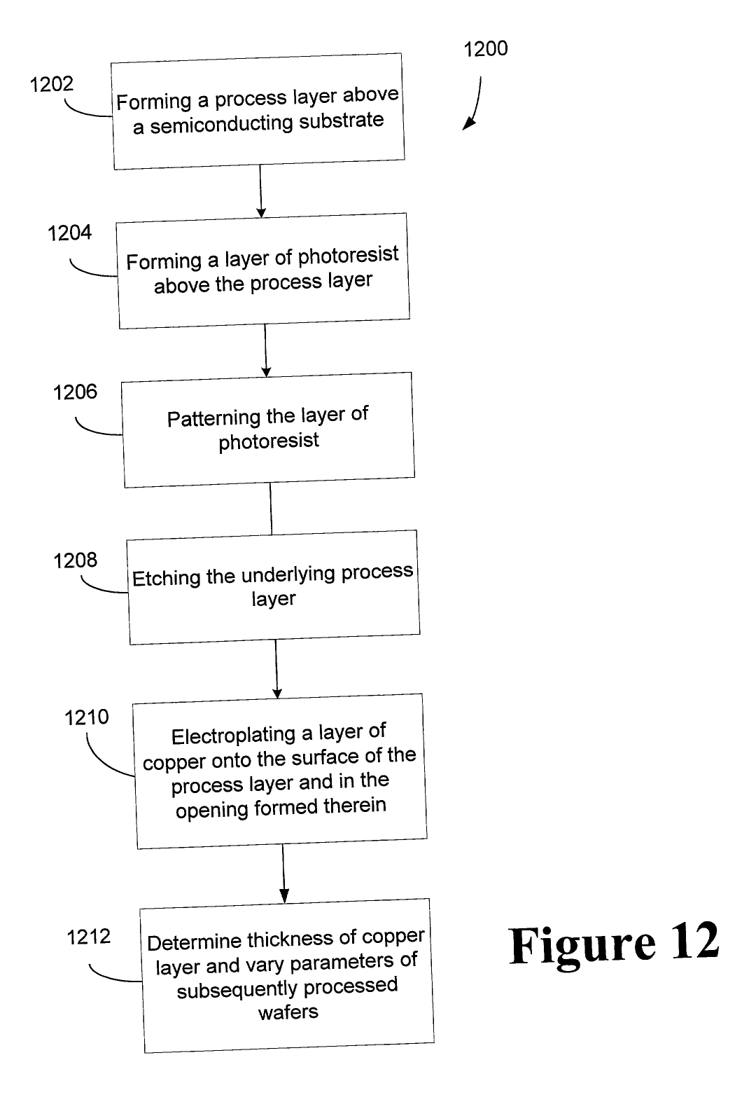

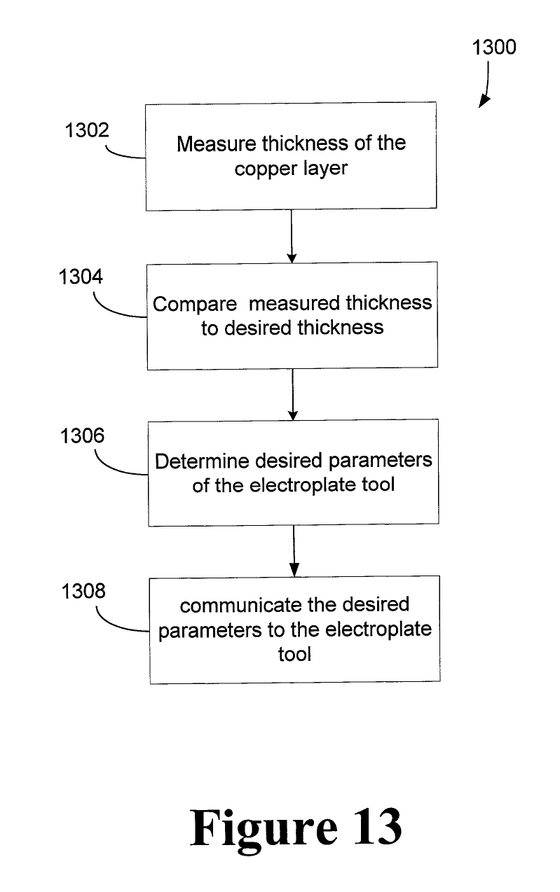

The controller 1012 of FIG. 10 may take a variety of forms. For example, the controller 1012 may be included within the tools 1004-1010, or it may be a separate device electrically coupled to the tools 1004-1010 via lines 1014-1020, respectively. In the embodiment illustrated herein, the controller 1012 takes the form of a computer that is controlled by a variety of software programs. The software programs that directly relate to controlling and or monitoring the electroplate tool 1009 are discussed in greater detail below in conjunction with FIGS. 12-13. Those of ordinary skill in the art having the benefit of this disclosure will appreciate that the controller 1012 need not rely on software for its functionality, but rather, a hardware controller may be used to provide the functionality described herein and attributed to the controller 1012. Further, the controller 1012 need not be coupled only to the tools 1004-1010, but rather, could be coupled to and involved in controlling or collecting data from other devices involved in the manufacture of semiconductor devices.

In the illustrated embodiment, the automatic process controller 1012 is a computer programmed with software to implement the functions described. However, as will be appreciated by those of ordinary skill in the art, a hardware controller (not shown) designed to implement the particular functions may also be used. Moreover, the functions of the controller described herein may be performed by one or more processing units that may or may not be geographically dispersed. Portions of the invention and corresponding detailed description are presented in terms of software, or algorithms and symbolic representations of operations on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” or “displaying” or the like, refer to the actions and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

An exemplary software system capable of being adapted to perform the functions of the automatic process controller 1012, as described, is the KLA Tencor Catalyst system offered by KLA Tencor, Inc. The KLA Tencor Catalyst system uses Semiconductor Equipment and Materials International (SEMI) Computer Integrated Manufacturing (CIM) Framework compliant system technologies, and is based on the Advanced Process Control (APC) Framework. CIM (SEMI E81-0699—Provisional Specification for CIM Framework Domain Architecture) and APC (SEMI E93-0999—Provisional Specification for CIM Framework Advanced Process Control Component) specifications are publicly available from SEMI.

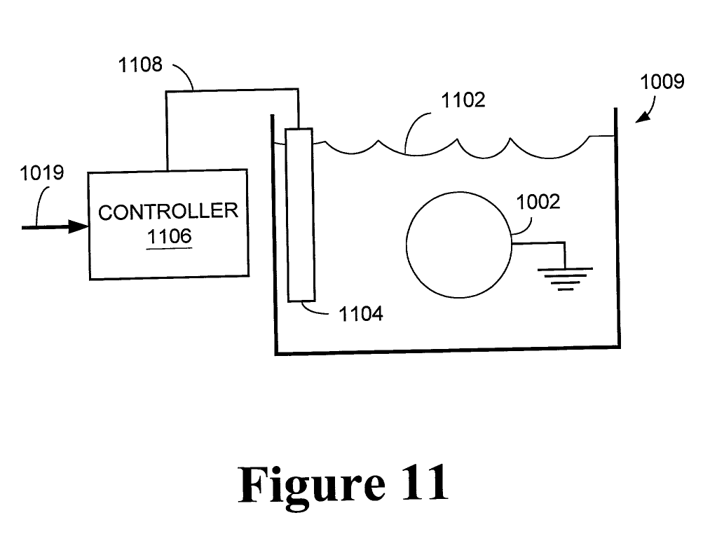

Turning now to FIG. 11, a stylized representation of the electroplater tool 1009 is shown. Generally, a tank 1100 contains a bath 1102. The wafer 1002 is immersed in the bath 1102 and coupled to electrical ground. Typically, the bath is composed of a salt of the metal to be plated. Thus, in the illustrated embodiment, the bath 1102 is a solution containing a copper salt, such as copper chloride, copper sulfate, or the like. A copper anode 1104 is also immersed in the bath 1102, and is coupled to receive an electrical signal from a controller 1106 over a line 1108. Thus, electricity flows from the copper anode to the grounded wafer 1002, transporting copper atoms from the anode 1104 to the bath 1102, and from the bath 1102 to the surface of the wafer 1002. The process continues for a preselected period of time to produce a conformal layer or film of copper similar to the layer 640 illustrated in FIG. 6. The electroplate tool 1009 may be any of a variety of devices capable of depositing a layer of copper on a semiconductor wafer. For example, an electroplate tool commercially available from Semitool as model LT-210t, Novellus as the Sabre model, or the like may be used.

The thickness of the copper layer 640 may be controlled by altering a variety of parameters. First, the duration that the wafer 1002 remains in the electrolytic solution 1102 with current passing from the anode 1104 to the wafer 1002 will directly impact the thickness of the copper layer 140. That is, reducing the period of time will reduce the thickness of the copper layer 640, and increasing the period of time will increase the thickness of the copper layer. The rate at which the thickness of the copper layer increases may not be constant, but rather, may vary over time, depending upon the condition of the anode 1104 and the bath 1102. Moreover, the type of features present on the wafer 1002 may also impact the rate. For example, increasing the number of features may produce a greater surface area, which may impact the rate at which the thickness of the copper layer 640 increases.

Varying the voltage and/or current applied to the anode 1104 may also impact the rate at which the thickness of the copper layer 640 increases. For example, increasing the voltage/current may raise the rate at which copper is deposited on the wafer 1002. Conversely, lowering the voltage/current may reduce the rate at which copper is deposited on the wafer 1002. Generally, maintaining the voltage applied to the copper anode 1104 in the range of about 2 to 4 volts produces acceptable electroplating characteristics.

Additionally, the controller 1106 may be configured to provide an AC signal. Varying the frequency, magnitude, and/or shape of the AC signal may also also impact the rate at which the thickness of the copper layer 640 increases. For example, increasing the current may raise the rate at which copper is deposited on the wafer 1002. Conversely, lowering the current may reduce the rate at which copper is deposited on the wafer 1002. Generally, maintaining the current applied to the copper anode 1104 in the range of about 1 to 10 milliamps produces acceptable electroplating characteristics.

The controller 1106 of the electroplate tool 1019 is coupled to the controller 1012 over the line 1019. This connection allows the controller 1012 to deliver signals that instruct the controller 1106 to vary some or all of the parameters discussed above to alter the thickness of the copper layer 640 based on data received from the metrology tool 1010. For example, if the metrology tool 1010 detects that the copper layer 640 is too thin, then the controller 1012 delivers a control signal to the controller 1106, instructing the controller 1106 to alter one or more of its parameters to increase the thickness of the copper layer 640.

Referring to FIG. 12, one illustrative embodiment of a process 1200 used to produce features of the type depicted in FIGS. 1-9 is generally shown in flowchart form. As shown therein, the present invention comprises the process 1200 beginning at block 1202 where a process layer is formed on the wafer 1200. Thereafter, a layer of photoresist is formed above the process layer, as indicated at block 1204. The method further comprises patterning the layer of photoresist, as indicated at block 1206, and etching away select portions of the underlying process layer, as indicated at block 1208. In block 1210, a layer of copper is formed on the surface of the process layer and in the openings created by the etching process. Thereafter, in block 1212, the wafer 1002 is analyzed to determine the thickness of the copper layer. The controller 1012 uses the thickness measurement to vary the parameters of the copper forming process so as to increase/decrease the thickness of subsequently formed copper layers, as needed.

Turning now to FIG. 13, a flowchart depiction of a process 1300 used to vary the parameters of the electroplate tool 1009, as identified in the block 1212, is shown. The process 1300 begins at block 1302 with the metrology tool 1010 measuring the thickness of the copper layer 640. The thickness of the copper layer 640 may be determined using a variety of processes. For example, a single measurement may be taken. Alternatively, a plurality of measurements may be made at preselected spaced apart locations on the surface of the wafer 1002. Where a plurality of measurements are made, a criteria may be established for determining the thickness of the layer 640. The criteria may involve averaging the measurements, determining the median value, using the worst case measurement, using the best case measurement, using a ruling majority of measurements, etc. In block 1302, the selected criteria is applied to the measurements to determine the actual thickness of the copper layer 640.

In block 1304, the actual thickness of the copper layer 640 is compared to a desired thickness. As long as the two measurements are within acceptable limits of one another, no action is taken to vary the parameters of the electroplate tool 1009. Where the comparison of the measurements is outside a desired range, the magnitude of the difference is recorded along with an indication of whether the actual thickness is greater or less than the desired thickness.

In an alternative embodiment, where a plurality of spatially separated measurements of the thickness of the copper layer 640 are made, it may be useful to compare each of these measurements to a desired thickness. In this embodiment, the desired thickness may be the same for each measurement, or it may vary. That is, a desired thickness at position A on the wafer 1002 may be greater or less than a desired thickness at position B.

In block 1306, the process 1300 determines a desired parameter for the electroplate tool 1009 so as to produce the desired thickness of the copper layer 640. Determining the desired parameter may be accomplished by a formula and/or a lookup table. The values stored in the lookup table and/or the formula may be derived theoretically, or may be determined empirically. That is, a formula that correlates the thickness of the copper layer with parameters, such as time, voltage, current, waveshape, frequency, etc. may be used to calculate the desired setting for the electroplate tool 1009. Alternatively, a series of test runs at a variety of times, voltages, currents, waveshapes, frequencies, etc. may be performed to determine an actual thickness of the copper layer 640 at a variety of these parameters. These empirically determined parameters may then be stored in a lookup table and accessed by the process 1300. Alternatively, the desired parameter of the electroplate tool 1009 may be iteratively adjusted until a desired thickness for the copper layer 640 is observed by the metrology tool 1010. That is, each time a wafer 102 is processed by the electroplate tool 1009 and measured by the metrology tool 1010, the desired parameter may be iteratively adjusted by an amount proportional to the difference between the desired and actual thickness. That is, the greater the difference in thickness, the greater the correction to the desired parameter.

Finally, in block 1308, the desired parameter is communicated to the electroplate tool 1009. The controller 1106 in the electroplate tool 1009 responds by varying the parameter to its new, desired setting for subsequently processed wafers 1002.

The present invention may be employed on a lot-by-lot basis and/or on a wafer-by-wafer basis. In general, the more frequent the measurements, the more uniform and accurate will be the electroplate process performed by the electroplate tool 1009. That is, the thickness of the copper layer 640 need not be measured on each wafer 102, but rather, a previous measurement may be used by the controller 1012 to control the parameters of the electroplate tool 1009 to produce the desired thickness of the copper layer 640. The number of wafers processed between measurements is a matter of design discretion, which depends substantially on the details of the particular embodiment.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. In particular, every range of values (of the form, “from about a to about b,” or, equivalently, “from approximately a to b,” or, equivalently, “from approximately a-b”) disclosed herein is to be understood as referring to the power set (the set of all subsets) of the respective range of values, in the sense of Georg Cantor. Accordingly, the protection sought herein is as set forth in the claims below.

What is claimed:

1. A method comprising:
forming a first dielectric layer above a first structure layer;
forming a first opening in the first dielectric layer;
forming a first copper layer above the first dielectric layer and in the first opening; and
measuring an actual thickness of the copper layer;
comparing the actual thickness to a desired thickness; and
varying at least one parameter used to form the first copper layer in response to the actual thickness differing from the desired thickness.

2. The method of claim 1, wherein forming the first dielectric layer comprises forming the first dielectric layer using a dielectric material having a dielectric constant K of at most about four, and forming the first dielectric layer using at least one of a chemical vapor deposition (CVD) process, a low-pressure CVD (LPCVD) process, a plasma-enhanced CVD (PECVD) process, a sputtering process, a physical vapor deposition (PVD) process, and a spin-on coating process.

3. The method of claim 1, wherein forming the first opening in the first dielectric layer comprises forming the first opening in the first dielectric layer using one of a mask of photoresist and an etch stop layer, the one of the mask of photoresist and the etch stop layer being formed and patterned above the first dielectric layer.

4. The method of claim 3, wherein using the one of the mask of photoresist and the etch stop layer comprises using the etch stop layer being formed of silicon nitride.

5. The method of claim 1, wherein forming the copper layer comprises forming the copper layer using electrochemical deposition of copper.

6. The method of claim 5, wherein using the electrochemical deposition of the copper comprises forming at least one barrier layer and a copper seed layer in the first opening before the electrochemical deposition of the copper.

7. The method of claim 1, wherein measuring the actual thickness of the copper layer further comprises measuring the actual thickness of the copper layer at a plurality of locations.

8. The method of claim 7, wherein measuring the actual thickness of the copper layer at a plurality of locations further comprises averaging the plurality of measurements of the actual thickness.

9. The method of claim 7, wherein measuring the actual thickness of the copper layer at a plurality of locations further comprises selecting a median measurement as the actual thickness.

10. The method of claim 7, wherein comparing the actual thickness to the desired thickness further comprises comparing the desired thickness to each of the plurality of measured thickness.

11. The method of claim 8, wherein comparing the actual thickness to the desired thickness further comprises comparing the desired thickness to the averaged measured thickness.

12. The method of claim 9, wherein comparing the actual thickness to the desired thickness further comprises comparing the desired thickness to the median thickness.

13. The method of claim 1, wherein forming the first copper layer further comprises electroplating the first copper layer above the first dielectric layer and in the first opening.

14. The method of claim 13, wherein varying at least one parameter used to form the first copper layer in response to the actual thickness differing from the desired thickness further comprises varying an amount of time that the first copper layer is electroplated above the first dielectric layer and in the first opening.

15. The method of claim 14, wherein varying at least one parameter used to form the first copper layer in response to the actual thickness differing from the desired thickness further comprises increasing the amount of time that the first copper layer is electroplated above the first dielectric layer and in the first opening in response to the desired thickness being greater than the actual thickness.

16. The method of claim 14, wherein varying at least one parameter used to form the first copper layer in response to the actual thickness differing from the desired thickness further comprises decreasing the amount of time that the first copper layer is electroplated above the first dielectric layer and in the first opening in response to the desired thickness being less than the actual thickness.

17. The method of claim 13, wherein varying at least one parameter used to form the first copper layer in response to the actual thickness differing from the desired thickness further comprises varying at least one of a current and voltage applied to an anode while electroplating the layer of copper above the first dielectric layer and in the first opening.

18. The method of claim 17, wherein varying at least one of a current and voltage further comprises increasing at least one of the current and voltage while the first copper layer is electroplated above the first dielectric layer and in the first opening in response to the desired thickness being greater than the actual thickness.

19. The method of claim 17, wherein varying at least one of a current and voltage further comprises decreasing at least one of the current and voltage while the first copper layer is electroplated above the first dielectric layer and in the first opening in response to the desired thickness being less than the actual thickness.

20. The method of claim 17, wherein varying at least one of the current and voltage further comprises varying the frequency of at least one of the current and voltage.

21. The method of claim 17, wherein varying at least one of the current and voltage further comprises varying the magnitude of at least one of the current and voltage.

22. A system, comprising:
means for forming a first dielectric layer above a first structure layer;
means for forming a first opening in the first dielectric layer;
means for forming a first copper layer above the first dielectric layer and in the first opening;
means for measuring an actual thickness of the copper layer;
means for comparing the actual thickness to a desired thickness; and
means for varying at least one parameter used to form the first copper layer in response to the actual thickness differing from the desired thickness.

23. A system, comprising:
an electroplate tool capable of depositing a layer of copper above a surface of a semiconductor device, said electroplate tool having at least one parameter that may be varied to control a thickness of the layer of copper;
a metrology tool capable of measuring the thickness of the copper layer and delivering a signal indicative thereof; and
a controller adapted for receiving the signal, comparing the measured thickness to a desired thickness, and varying the at least one parameter in response to the measured thickness differing from the desired thickness.

24. The system of claim 23, wherein the controller varying the at least one parameter further comprises the controller varying an amount of time that the first copper layer is electroplated above the surface of the semiconductor device.

25. The system of claim 24, wherein the controller further comprises the controller being adapted for increasing the amount of time that the first copper layer is electroplated above the surface of the semiconductor device in response to the desired thickness being greater than the actual thickness.

26. The system of claim 24, wherein the controller further comprises the controller being adapted for decreasing the amount of time that the first copper layer is electroplated above the surface of the semiconductor device in response to the desired thickness being less than the actual thickness.

27. The system of claim 23, wherein the controller further comprises the controller being adapted for varying at least one of a current and voltage applied to an anode of the electroplate tool while electroplating the layer of copper above the surface of the semiconductor device.

28. The system of claim 27, wherein the controller further comprises the controller being adapted for increasing at least one of the current and voltage while the first copper layer is electroplated above the surface of the semiconductor device in response to the desired thickness being greater than the actual thickness.

29. The system of claim 27, wherein the controller comprises the controller being adapted for decreasing at least one of the current and voltage while the first copper layer is electroplated above the surface of the semiconductor device in response to the desired thickness being less than the actual thickness.

30. The system of claim 27, wherein the controller further comprises the controller being adapted for varying the frequency of at least one of the current and voltage.

31. The system of claim 27, wherein the controller further comprises the controller being adapted for varying the magnitude of at least one of the current and voltage.
